(19) United States
(12) Patent Application Publication
(10) Pub. No.: US 2024/0421152 A1
(43) Pub. Date: Dec. 19, 2024

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Yuki SAWA, Matsumoto-city (JP); Motoyoshi KUBOUCHI, Matsumoto-city (JP); Kota OHI, Matsumoto-city (JP)

(21) Appl. No.: 18/818,617

(22) Filed: Aug. 29, 2024

Related U.S. Application Data
(63) Continuation of application No. PCT/JP2023/023416, filed on Jun. 23, 2023.

(30) Foreign Application Priority Data
Sep. 14, 2022 (JP) 2022-146061

(51) Int. Cl. H01L 27/06; H01L 21/265; H01L 29/06; H01L 29/10; H01L 29/32; H01L 29/739; H01L 29/861

(52) U.S. Cl. CPC H01L 27/0664; H01L 21/26513; H01L 29/0623; H01L 29/1095; H01L 29/32; H01L 29/7397; H01L 29/8613

(57) ABSTRACT

Provided is a semiconductor device provided with a vertical element, where the vertical element has: a drift region of a first conductivity type provided in a semiconductor substrate; a first implantation portion provided below the drift region; and a second implantation portion provided below the drift region and having lower carrier implantation efficiency than the first implantation portion, an area of the first implantation portion is larger than an area of the second implantation portion at a back surface of the semiconductor substrate, and the vertical element has the first implantation portion and the second implantation portion which are alternately provided in a predetermined direction.

The contents of the following patent application(s) are incorporated herein by reference:
NO. 2022-146061 filed in JP on Sep. 14, 2022
NO. PCT/JP2023/023416 filed in WO on Jun. 23, 2023

### BACKGROUND

### 1. Technical Field

The present invention relates to a semiconductor device and a method for manufacturing a semiconductor device.

### 2. Related Art

Patent Document 1 describes that “the first low implantation region 27 may be provided sandwiched in the Y-axis direction between the collector regions 22 provided at the respective ends of the transistor portion 70, on the bottom surface side of the semiconductor substrate 10”.

### PRIOR ART DOCUMENT

### Patent Document

Patent Document 1: Japanese Patent Application Publication No. 2019-161168
Patent Document 2: Japanese Patent Application Publication No. 2005-333055
Patent Document 3: Japanese Patent Application Publication No. 2000-4017

### BRIEF DESCRIPTION OF THE DRAWINGS

FIG. 1A is a figure showing one example of an upper surface of a semiconductor device 100.

FIG. 1B is a figure showing one example of a cross section taken along a line a-a′ in FIG. 1A.

FIG. 1C is a figure showing one example of a lower surface of the semiconductor device 100.

FIG. 1D is a figure showing one example of a lower surface of a modified example of the semiconductor device 100.

FIG. 1E is a figure showing one example of a lower surface of a modified example of the semiconductor device 100.

FIG. 1F is a figure showing one example of a lower surface of a modified example of the semiconductor device 100.

FIG. 1G is a figure showing one example of a lower surface of a modified example of the semiconductor device 100.

FIG. 2 is a figure showing a top view of a modified example of the semiconductor device 100.

FIG. 3A is an enlarged view of an upper surface of a region A in FIG. 2.

FIG. 3B is a figure showing one example of a cross section taken along a line c-c′ in FIG. 3A.

FIG. 4 is a figure showing one example of a cross section taken along a line b-b′ in FIG. 2.

FIG. 5 is an enlarged view of an upper surface of a region C in FIG. 2.

FIG. 6 is a figure showing a relationship between an area percentage of a first implantation portion 171 and Von-Eoff in a transistor portion 70.

FIG. 7A is a figure showing one example of a cross section of a modified example of the semiconductor device 100.

FIG. 7B is a figure showing one example of a cross section of a modified example of the semiconductor device 100.

FIG. 7C is a figure showing one example of a cross section of a modified example of the semiconductor device 100.

FIG. 7D is a figure showing one example of a cross section of a modified example of the semiconductor device 100.

FIG. 8 is a figure showing a relationship between an area percentage of a first implantation portion 171 and Von-Eoff in a transistor portion 70.

FIG. 9 is a flowchart showing one example of a process of manufacturing a semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One surface of two principal surfaces of a substrate, a layer or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It should be noted that the +Z axis direction and the −Z axis direction are directions opposite to each other. If the Z axis direction is described without describing the signs, it means that the direction is parallel to the +Z axis and the −Z axis.

In the present specification, a surface parallel to the upper surface of the semiconductor substrate is referred to as the XY surface, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. It should be noted that, in the present specification, a case where the semiconductor substrate is viewed in the Z axis direction is referred to as a plan view. In addition, in the present specification, a direction parallel to the upper surface and the lower surface of the semiconductor substrate may be referred to as a horizontal direction, including the X axis direction and the Y axis direction.

Each embodiment example shows an example in which a first conductivity type is set as an N type, and a second conductivity type is set as a P type, however, the first conductivity type may be the P type, and the second conductivity type may be the N type. In this case, conductivity types of the substrate, the layer, a region, and the like in each embodiment example respectively have opposite polarities.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state.

In the present specification, a description of a P+ type or an N+ type means a higher doping concentration than that of the P type or the N type, and a description of a P− type or an N-type means a lower doping concentration than that of the P type or the N type.

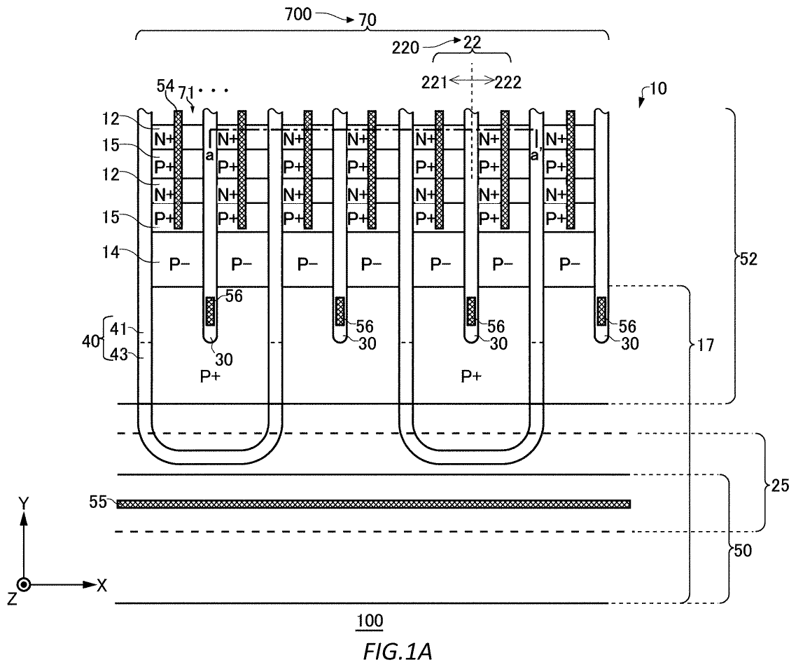

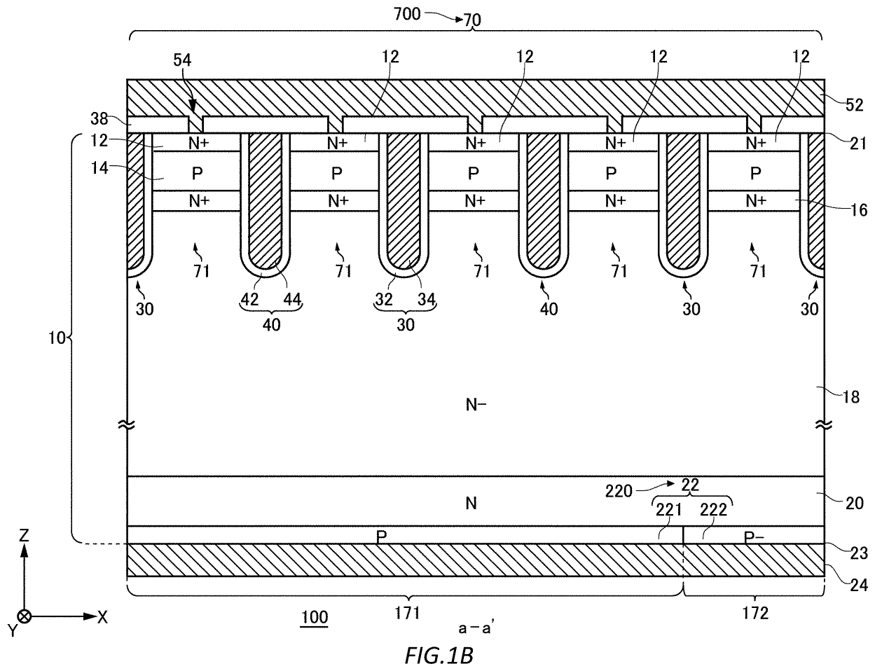

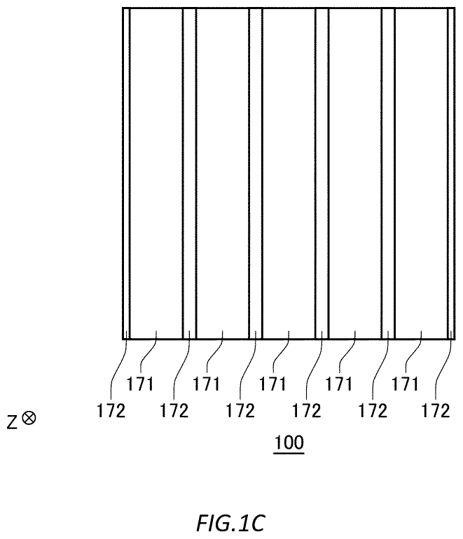

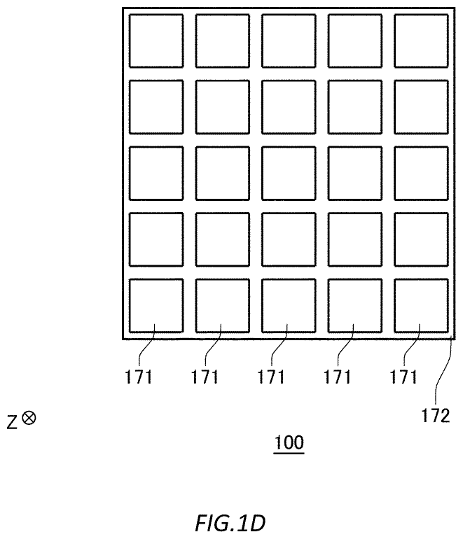

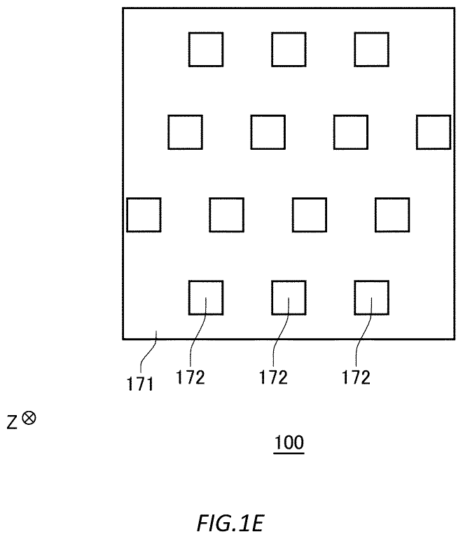

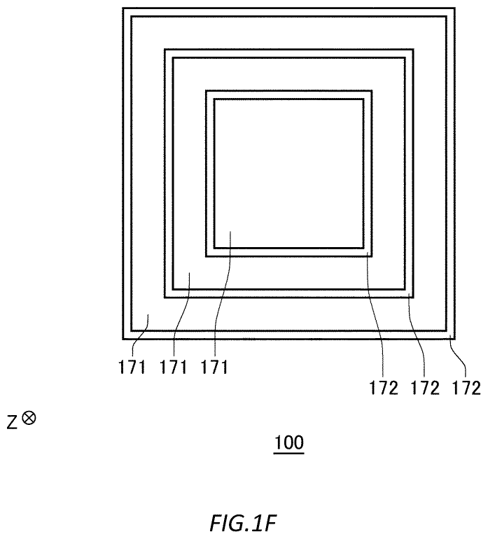

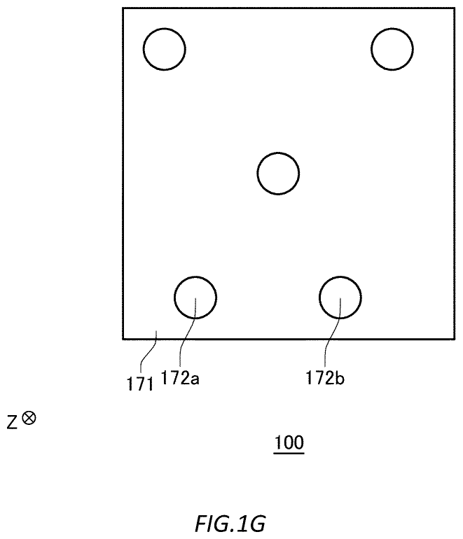

FIG. 1A shows one example of an upper surface of a semiconductor device 100. The semiconductor device 100 in the present example is a semiconductor chip including at least a transistor portion 70. The transistor portion 70 is one example of a vertical element 700. That is, the vertical element 700 may have the transistor portion 70. The vertical element 700 may be described below as the transistor portion 70. A feature described as a feature of the transistor portion 70 may be a feature of the vertical element 700. For example, the semiconductor device 100 is a reverse conducting IGBT (RC-IGBT). As another example, the semiconductor device 100 may be an IGBT, may be a bipolar PIN diode, may be a MOSFET, or may be a schottky barrier diode. It is to be noted that the semiconductor device 100 is not limited thereto. In this manner, the vertical element 700 included in the semiconductor device 100 may have a PN junction where a region of a first conductivity type and a region of a second conductivity type are in contact with each other.

The transistor portion 70 is a region obtained by projecting a collector region 22 provided on a back surface side of a semiconductor substrate 10 onto an upper surface of the semiconductor substrate 10. The collector region 22 is one example of an implantation region 220. The collector region 22 and the implantation region 220 will be described later. The transistor portion 70 includes a transistor such as the IGBT. The transistor portion 70 may include a transistor such as the MOSFET.

FIG. 1A shows a region around a chip end portion, which is an edge side of the semiconductor device 100, and other regions are omitted. For example, an edge termination structure portion may be provided in a region of the semiconductor device 100 in the present example on a negative side in the Y axis direction. The edge termination structure portion reduces electric field strength on an upper surface side of the semiconductor substrate 10. The edge termination structure portion has, for example, a guard ring, a field plate, a RESURF, and a structure combining them. It should be noted that, although the present example describes for convenience an edge on the negative side in the Y axis direction, the same applies to another edge of the semiconductor device 100. The edge termination structure portion may be provided so as to enclose an active region including the transistor portion 70.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 in the present example includes, at a front surface 21 of the semiconductor substrate 10, gate trench portions 40, dummy trench portions 30, emitter regions 12, base regions 14, contact regions 15, and a well region 17. The front surface 21 will be described later. In addition, the semiconductor device 100 in the present example includes an emitter electrode 52 and a gate metal layer 50 which are provided above the front surface 21 of the semiconductor substrate 10.

The emitter electrode 52 is provided above the gate trench portions 40, the dummy trench portions 30, the emitter regions 12, the base regions 14, the contact regions 15, and the well region 17. In addition, the gate metal layer 50 is provided above a connecting portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). The emitter electrode 52 and the gate metal layer 50 may have a barrier metal layer formed of titanium, a titanium compound, or the like under a region formed of aluminum or the like. The emitter electrode 52 and the gate metal layer 50 are provided separate from each other.

The emitter electrode 52 and the gate metal layer 50 are provided above the semiconductor substrate 10 with an interlayer dielectric film 38 sandwiched therebetween. The interlayer dielectric film 38 is omitted in FIG. 1A. Contact holes 54, a contact hole 55, and contact holes 56 are provided penetrating the interlayer dielectric film 38.

The contact hole 55 electrically connects the gate metal layer 50 and gate conductive portions in the transistor portion 70 via the connecting portion 25. A plug layer formed of tungsten or the like may be formed inside the contact hole 55.

The contact holes 56 connect the emitter electrode 52 and dummy conductive portions in the dummy trench portions 30. Plug layers formed of tungsten or the like may be formed inside the contact holes 56.

A connecting portion 25 is connected to a front surface side metal layer such as the emitter electrode 52 or the gate metal layer 50. In one example, the connecting portion 25 is provided between the gate metal layer 50 and the gate conductive portions. The connecting portion 25 in the present example may be provided extending in the X axis direction, and electrically connected to the gate conductive portions. The connecting portion 25 may be provided also between the emitter electrode 52 and the dummy conductive portions. In the present example, a connecting portion 25 is not provided between the emitter electrode 52 and the dummy conductive portions. The connecting portion 25 is made of a conductive material such as polysilicon doped with impurities. The connecting portion 25 in the present example is formed of polysilicon doped with impurities of the N type (N+). The connecting portion 25 is provided above the front surface 21 of the semiconductor substrate 10 via a dielectric film such as an oxide film, or the like.

The gate trench portions 40 are examples of a plurality of trench portions extending in a predetermined extending direction on a front surface 21 side of the semiconductor substrate 10. The gate trench portions 40 are arrayed at a predetermined interval along a predetermined array direction (the X axis direction in the present example). A gate trench portion 40 in the present example may have: two extending parts 41 which extend along an extending direction (the Y axis direction in the present example) parallel to the front surface 21 of the semiconductor substrate 10 and perpendicular to the array direction; and a connecting part 43 which connects the two extending parts 41.

It is preferable that the connecting part 43 is at least partially formed in a curved shape. Connecting end portions of the two extending parts 41 of the gate trench portion 40 can reduce electric field strength at the end portions of the extending parts 41. At the connecting part 43 of the gate trench portion 40, the gate metal layer 50 may be electrically connected to a gate conductive portion via the connecting portion 25.

The dummy trench portions 30 are examples of a plurality of trench portions extending in a predetermined extending direction on the front surface 21 side of the semiconductor substrate 10. The dummy trench portions 30 are trench portions electrically connected to the emitter electrode 52. The dummy trench portions 30, like the gate trench portions 40, are arrayed at a predetermined interval along a predetermined array direction (the X axis direction in the present example). The dummy trench portions 30 in the present example have an I shape at the front surface 21 of the semiconductor substrate 10, but like the gate trench portions 40, they may have a U shape at the front surface 21 of the semiconductor substrate 10. That is, a dummy trench portion 30 may have: two extending parts which extend along the extending direction; and a connecting part which connects the two extending parts.

The transistor portion 70 in the present example has a structure in which two gate trench portions 40 and two dummy trench portions 30 are repetitively arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It is to be noted that a ratio between the gate trench portions 40 and the dummy trench portions 30 is not limited to the ratio in the present example. A ratio of the gate trench portions 40 may be larger than a ratio of the dummy trench portions 30, or a ratio of the dummy trench portions 30 may be larger than a ratio of the gate trench portions 40. The ratio between the gate trench portions 40 and the dummy trench portions 30 may be 2:3, or may be 2:4. In addition, the transistor portion 70 may not have a dummy trench portion 30 with all the trench portions as gate trench portions 40.

The well region 17 is a region of the second conductivity type provided on the front surface 21 side of the semiconductor substrate 10 relative to a drift region 18 which will be described later. The well region 17 is one example of a well region provided on a side of a periphery of an active region 120. The well region 17 is of the P+ type, as one example. The well region 17 is formed in a predetermined range from an end portion of an active region on a side where the gate metal layer 50 is provided. A diffusion depth of the well region 17 may be greater than depths of the gate trench portions 40 and the dummy trench portions 30. Partial regions of the gate trench portions 40 and the dummy trench portions 30 on a gate metal layer 50 side are formed in the well region 17. Bottoms of ends of the gate trench portions 40 and the dummy trench portions 30 in the extending direction may be covered with the well region 17.

The contact holes 54 are formed above respective regions of the emitter regions 12 and the contact regions 15 in the transistor portion 70. Contact holes 54 are not provided above well regions 17 provided at their both ends in the Y axis direction. In this manner, one or more contact holes 54 are formed in the interlayer dielectric film. The one or more contact holes 54 may be provided extending in the extending direction.

A mesa portion 71 is a mesa portion provided in direct contact with a trench portion in a plane parallel to the front surface 21 of the semiconductor substrate 10. The mesa portion may be a part of the semiconductor substrate 10 which is sandwiched between two adjacent trench portions, and may be a part extending from the front surface 21 of the semiconductor substrate 10 to a depth of the lowermost bottom portion of each trench portion. An extending part of each trench portion may be defined as one trench portion. That is, a region sandwiched between two extending parts may be defined as the mesa portion.

The mesa portion 71 is provided in direct contact with at least one of the dummy trench portion 30 or the gate trench portion 40 in the transistor portion 70. The mesa portion 71 has, at the front surface 21 of the semiconductor substrate 10, the well region 17, emitter regions 12, a base region 14, and contact regions 15. In the mesa portion 71, the emitter regions 12 and the contact regions 15 are alternately provided in the extending direction.

The base region 14 is a region of the second conductivity type provided on the front surface 21 side of the semiconductor substrate 10. The base region 14 is of the P− type, as one example. Base regions 14 may be provided at both end portions of the mesa portion 71 in the Y axis direction at the front surface 21 of the semiconductor substrate 10. It should be noted that FIG. 1A shows only one end portion of the base regions 14 in the Y axis direction.

The emitter regions 12 are regions of a first conductivity type having a higher doping concentration than the drift region 18. The emitter regions 12 in the present example are of the N+ type, as one example. Examples of dopants of the emitter regions 12 include arsenic (As). The emitter regions 12 are provided in contact with the gate trench portion 40 at the front surface 21 in the mesa portion 71. The emitter regions 12 may be provided extending in the X axis direction from one of two trench portions sandwiching the mesa portion 71 to another. The emitter regions 12 are provided also below a contact hole 54.

In addition, the emitter regions 12 may be or may not be in contact with the dummy trench portion 30. The emitter regions 12 in the present example are in contact with the dummy trench portion 30.

The contact regions 15 are regions of the second conductivity type provided above the base region 14 and having a higher doping concentration than the base region 14. The contact regions 15 in the present example are of the P+ type, as one example. The contact regions 15 in the present example are provided at the front surface 21 in the mesa portion 71. The contact regions 15 may be provided extending in the X axis direction from one of the two trench portions sandwiching the mesa portion 71 to another. The contact regions 15 may be or may not be in contact with the gate trench portion 40 or the dummy trench portion 30. The contact regions 15 in the present example are in contact with the dummy trench portion 30 and the gate trench portion 40. The contact regions 15 are provided also below the contact hole 54.

FIG. 1B shows one example of a cross section taken along a line a-a′ in FIG. 1A. The cross section taken along the line a-a′ is an XZ plane passing through emitter regions 12 in the transistor portion 70. The semiconductor device 100 in the present example has, in the cross section taken along the line a-a′, the semiconductor substrate 10, the interlayer dielectric film 38, the emitter electrode 52, and a back surface electrode 24. The emitter electrode 52 is formed above the semiconductor substrate 10 and the interlayer dielectric film 38.

The drift region 18 is a region of a first conductivity type provided in the semiconductor substrate 10. The drift region 18 in the present example is of the N− type, as one example. The drift region 18 may be a region of the semiconductor substrate 10 which is left without another doping region being formed therein. That is, the doping concentration in the drift region 18 may be a doping concentration in the semiconductor substrate 10.

A buffer region 20 is a region of the first conductivity type provided on a back surface 23 side of the semiconductor substrate 10 relative to the drift region 18. The buffer region 20 in the present example is of the N type, as one example. A doping concentration in the buffer region 20 is higher than the doping concentration in the drift region 18. The buffer region 20 may serve as a field stop layer to prevent a depletion layer expanding from a lower surface side of base regions 14 from reaching a first implantation region 221 and a second implantation region 222 of a second conductivity type. It should be noted that the buffer region 20 may be omitted.

In the present example, the transistor portion 70 has a first implantation portion 171 and a second implantation portion 172. The first implantation portion 171 has the first implantation region 221 and part of the back surface electrode 24. The second implantation portion 172 has the second implantation region 222 and part of the back surface electrode 24. It is to be noted that, as described later, the second implantation portion 172 may not have the back surface electrode 24. The second implantation portion 172 has lower implantation efficiency of carriers implanted from the back surface electrode 24 than the first implantation portion 171. At the back surface 23 of the semiconductor substrate 10, an area of the first implantation portion 171 may be larger than an area of the second implantation portion 172.

The first implantation portion 171 and the second implantation portion 172 may be alternately provided in a trench array direction (the X axis direction in the present example). The first implantation portion 171 and the second implantation portion 172 may be provided at a fixed repetition pitch. That is, a sum of a width of the first implantation portion 171 and a width of the second implantation portion 172 may be fixed. The fixed repetition pitch may correspond to 20, 40, or 100 times a distance between respective trench portions. The fixed repetition pitch may be 20 μm or greater, or may be 100 μm or smaller.

As long as the first implantation portion 171 and the second implantation portion 172 are alternately provided, the fixed repetition pitch may not be fixed. In addition, the first implantation portion 171 and the second implantation portion 172 may be alternately provided in a trench extending direction (the Y axis direction in the present example), or may be alternately provided in a direction different from the trench extending direction. A method for arranging the first implantation portion 171 and the second implantation portion 172 will be described later in detail. Providing the first implantation portion 171 and the second implantation portion 172 having lower carrier implantation efficiency than the first implantation portion 171 can adjust implantation efficiency of carriers in the transistor portion 70 and improve a Von-Eoff trade-off.

The collector region 22 is provided below the buffer region 20 in the transistor portion 70. The collector region 22 has the second conductivity type. The collector region 22 is one example of the implantation region 220. The implantation region 220 may be a region contributing to carrier implantation efficiency in the vertical element 700. As one example, if the vertical element 700 is a MOSFET, the implantation region 220 may be a drain region. As another example, if the vertical element 700 is a bipolar PIN diode, the implantation region 220 may be an anode region, or may be a cathode region. Also when the vertical element 700 is another element, the implantation region 220 may be the region contributing to the carrier implantation efficiency. The collector region 22 in the present example, which is the implantation region 220, may include the first implantation region 221 and the second implantation region 222.

The first implantation region 221 is provided below the buffer region 20 in the first implantation portion 171. The first implantation region 221 has the second conductivity type. The first implantation region 221 in the present example is of the P type, as one example. A conductivity type of the first implantation region 221 may be the same as a conductivity type of the implantation region 220. For example, if the implantation region 220 is of the first conductivity type, the conductivity type of the first implantation region 221 may also be of the first conductivity type.

The second implantation region 222 is provided below the buffer region 20 in the second implantation portion 172. The second implantation region 222 has the second conductivity type. The second implantation region 222 in the present example is of the P− type, as one example. A conductivity type of the second implantation region 222 may be the same as the conductivity type of the implantation region 220. For example, if the implantation region 220 is of the first conductivity type, the conductivity type of the second implantation region 222 may also be the first conductivity type.

A doping concentration in the first implantation region 221 may be 1E16 cm⁻³ or higher and 1E18 cm⁻³ or lower. It should be noted that, in the present specification, E represents a power of 10. For example, 1E16 means 1×10¹⁶.

A doping concentration in the second implantation region 222 may be lower than the doping concentration in the first implantation region 221. In one example, the doping concentration in the second implantation region 222 may be 1E15 cm⁻³ or higher. Ensuring this concentration can suppress snapback. In addition, the doping concentration in the second implantation region 222 may be equal to or lower than 0.5 times the doping concentration in the first implantation region 221.

The first implantation region 221 and the second implantation region 222 may be formed by implanting impurities from the front surface 21 or the back surface 23 of the semiconductor substrate 10. In one example, the first implantation region 221 may be selectively formed by masking part of the back surface 23 of the semiconductor substrate 10 and implanting additional impurities after forming the second implantation region 222 by implanting the impurities into its entire surface from the back surface 23 of the semiconductor substrate 10. A mask may be any mask such as a photoresist. The impurities for forming the first implantation region 221 and the second implantation region 222 may be, as one example, boron (B) or the like.

The back surface electrode 24 is formed at the back surface 23 of the semiconductor substrate 10. The back surface electrode 24 is formed of a conductive material such as metal. A material of the back surface electrode 24 may be the same as or different from a material of the emitter electrode 52.

The base regions 14 are regions of the second conductivity type provided above the drift region 18. A base region 14 is provided in contact with a gate trench portion 40. A base region 14 may be provided in contact with a dummy trench portion 30.

An emitter region 12 is provided above the base region 14. The emitter region 12 is provided between the base region 14 and the front surface 21. The emitter region 12 is provided in contact with the gate trench portion 40. The emitter region 12 may be or may not be in contact with the dummy trench portion 30.

Accumulation regions 16 are regions of the first conductivity type provided on a front surface 21 side of the semiconductor substrate 10 relative to the drift region 18. The accumulation regions 16 in the present example are of the N+ type, as one example. It is to be noted that accumulation regions 16 may not be provided. Providing the accumulation regions 16 can increase a carrier implantation enhancement effect (IE effect) to reduce an on-voltage of the transistor portion 70.

One or more gate trench portions 40 and one or more dummy trench portions 30 are provided at the front surface 21. Each trench portion is provided extending from the front surface 21 to the drift region 18. In a region provided with at least any of the emitter regions 12, the base regions 14, contact regions 15, or the accumulation regions 16, each trench portion penetrates these regions as well to reach the drift region 18. A configuration in which a trench portion penetrates a doping region is not limited to a configuration which is manufactured by forming a doping region and forming a trench portion in this order. A configuration which is manufactured by forming trench portions and then forming a doping region between the trench portions is also included in a configuration in which a trench portion penetrates a doping region.

The gate trench portion 40 has a gate trench, a gate dielectric film 42, and a gate conductive portion 44 which are formed at the front surface 21. The gate dielectric film 42 is formed covering an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 at the front surface 21.

The gate conductive portion 44 includes, in the depth direction of the semiconductor substrate 10, regions opposing base regions 14 which are adjacent to the gate conductive portion 44 with the gate dielectric film 42 sandwiched therebetween, on a mesa portion 71 side. When a predefined voltage is applied to the gate conductive portion 44, channels are formed by electron inversion layers at surface layers of boundary surfaces of the base regions 14 which is in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on the front surface 21 side. The dummy dielectric film 32 is formed covering an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 at the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 and the semiconductor substrate 10. Similarly, the contact hole 55 and contact holes 56 may be provided penetrating the interlayer dielectric film 38. A film thickness of the interlayer dielectric film 38 is, for example, 1.0 μm, but is not limited thereto.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may include a high temperature silicon oxide (HTO: high temperature oxide) film.

FIG. 1C shows one example of a lower surface of the semiconductor device 100. FIG. 1C shows at least a partial region of the lower surface of the semiconductor device 100. That is, the region shown in FIG. 1C may be provided over an entirety of the lower surface of the semiconductor device 100, the region shown in FIG. 1C may be provided at part of the lower surface of the semiconductor device 100, or regions including the region shown in FIG. 1C may be repetitively provided at the lower surface of the semiconductor device 100.

The vertical element 700 may have first implantation portions 171 and second implantation portions 172 which are alternately provided in a predetermined direction. The first implantation portions 171 and the second implantation portions 172 in the present example each have a lateral length and a longitudinal length, and are provided extending in a longitudinal direction. The first implantation portions 171 and the second implantation portions 172 in the present example are alternately provided in a direction perpendicular to an extending direction of each implantation portion.

The predetermined direction may have a slope of 0 degrees or more and 90 degrees or less with respect to the trench extending direction. That is, an array direction of the first implantation portions 171 and the second implantation portions 172 may have the slope of 0 degrees or more and 90 degrees or less with respect to the trench extending direction (for example, the Y axis). FIG. 1C shows only the Z axis. That is, in FIG. 1C, the trench extending direction (for example, the Y axis) may be any direction perpendicular to the Z axis.

The vertical element 700 may have the first implantation portions 171 and the second implantation portions 172 which are regularly provided. The first implantation portions 171 and the second implantation portions 172 being regularly provided may mean the first implantation portions 171 and the second implantation portions 172 being alternately provided at the fixed repetition pitch. The first implantation portions 171 and the second implantation portions 172 in the present example are alternately provided at the fixed repetition pitch in the direction perpendicular to the extending direction of each implantation portion.

FIG. 1D shows one example of a lower surface of a modified example of the semiconductor device 100. FIG. 1D shows at least a partial region of the lower surface of the semiconductor device 100. That is, the region shown in FIG. 1D may be provided over an entirety of the lower surface of the semiconductor device 100, the region shown in FIG. 1D may be provided at part of the lower surface of the semiconductor device 100, or regions including the region shown in FIG. 1D may be repetitively provided at the lower surface of the semiconductor device 100.

First implantation portions 171 in the present example are repetitively arranged in a first direction perpendicular to the depth direction of the semiconductor substrate 10 (the Z axis in the present example) and in a second direction perpendicular to the first direction. A second implantation portion 172 in the present example is provided enclosing the first implantation portions 171. Accordingly, the vertical element 700 in the present example has the first implantation portions 171 and the second implantation portion 172 which are alternately provided in predetermined directions. The predetermined directions in the present example may also have the slope of 0 degrees or more and 90 degrees or less with respect to the trench extending direction. That is, in FIG. 1D, the trench extending direction (for example, the Y axis) may be any direction perpendicular to the Z axis. Contrary to the present example, a first implantation portion 171 may be provided enclosing second implantation portions 172 repetitively arranged in the first direction and the second direction. In this case, a repetition pitch, an area per repetition of a second implantation portion 172, or the like may be adjusted such that an area of the first implantation portion 171 is larger than an area of the second implantation portions 172.

FIG. 1E shows one example of a lower surface of a modified example of the semiconductor device 100. FIG. 1E shows at least a partial region of the lower surface of the semiconductor device 100. That is, the region shown in FIG. 1E may be provided over an entirety of the lower surface of the semiconductor device 100, the region shown in FIG. 1E may be provided at part of the lower surface of the semiconductor device 100, or regions including the region shown in FIG. 1E may be repetitively provided at the lower surface of the semiconductor device 100.

Second implantation portions 172 in the present example are symmetrically arranged about a point with respect to a center of the region shown in the figure. A first implantation portion 171 in the present example is provided enclosing the second implantation portions 172. Accordingly, the vertical element 700 in the present example has the first implantation portion 171 and the second implantation portions 172 which are alternately provided in a predetermined direction. For example, the predetermined direction in the present example may be any direction passing through the center of the point symmetry. The predetermined direction in the present example may also have the slope of 0 degrees or more and 90 degrees or less with respect to the trench extending direction. That is, in FIG. 1E, the trench extending direction (for example, the Y axis) may be any direction perpendicular to the Z axis.

FIG. 1F shows one example of a lower surface of a modified example of the semiconductor device 100. FIG. 1F shows at least a partial region of the lower surface of the semiconductor device 100. That is, the region shown in FIG. 1F may be provided over an entirety of the lower surface of the semiconductor device 100, the region shown in FIG. 1F may be provided at part of the lower surface of the semiconductor device 100, or regions including the region shown in FIG. 1F may be repetitively provided at the lower surface of the semiconductor device 100.

First implantation portions 171 in the present example, having a quadrangular shape and a quadrangular ring shape concentric with the quadrangular shape, are repetitively arranged in a radial direction from the center. Second implantation portions 172 in the present example, having a quadrangular ring shape concentric with the first implantation portions 171, are repetitively arranged in the radial direction from the center in regions where first implantation portions 171 are not provided. Accordingly, the vertical element 700 in the present example has the first implantation portions 171 and the second implantation portions 172 which are alternately provided in a predetermined direction. The predetermined direction in the present example may also have the slope of 0 degrees or more and 90 degrees or less with respect to the trench extending direction. That is, in FIG. 1F, the trench extending direction (for example, the Y axis) may be any direction perpendicular to the Z axis. Contrary to the present example, a second implantation portion 172 having a quadrangular shape may be arranged at the center, and first implantation portions 171 and second implantation portions 172 having a quadrangular ring shape may be repetitively arranged around the quadrangular shape. In this case, a length or the like of each portion may be adjusted such that an area of the first implantation portions 171 is larger than an area of the second implantation portions 172.

FIG. 1G shows one example of a lower surface of a modified example of the semiconductor device 100. FIG. 1G shows at least a partial region of the lower surface of the semiconductor device 100. That is, the region shown in FIG. 1G may be provided over an entirety of the lower surface of the semiconductor device 100, the region shown in FIG. 1G may be provided at part of the lower surface of the semiconductor device 100, or regions including the region shown in FIG. 1G may be repetitively provided at the lower surface of the semiconductor device 100.

Second implantation portions 172 in the present example are irregularly arranged. A first implantation portion 171 in the present example is provided enclosing the second implantation portions 172 in a region where a second implantation portion 172 is not provided. Also in the present example, the vertical element 700 has the first implantation portion 171 and the second implantation portions 172 which are alternately provided in a predetermined direction. For example, in a direction in which a center of a second implantation portion 172a and a center of a second implantation portion 172b are connected, the first implantation portion 171 and the second implantation portions 172 are alternately provided. The predetermined direction in the present example may also have the slope of 0 degrees or more and 90 degrees or less with respect to the trench extending direction. That is, in FIG. 1G, the trench extending direction (for example, the Y axis) may be any direction perpendicular to the Z axis.

As described above, the vertical element 700 in the present example has the first implantation portion 171 and the second implantation portions 172 which are alternately provided in the predetermined direction. A carrier distribution inside the vertical element 700 can be modulated by alternately providing the first implantation portion 171 and the second implantation portions 172 having lower implantation efficiency of carriers implanted from the back surface electrode 24 than the first implantation portion 171. Modulating the carrier distribution in the vertical element 700 can improve the Von-Eoff trade-off.

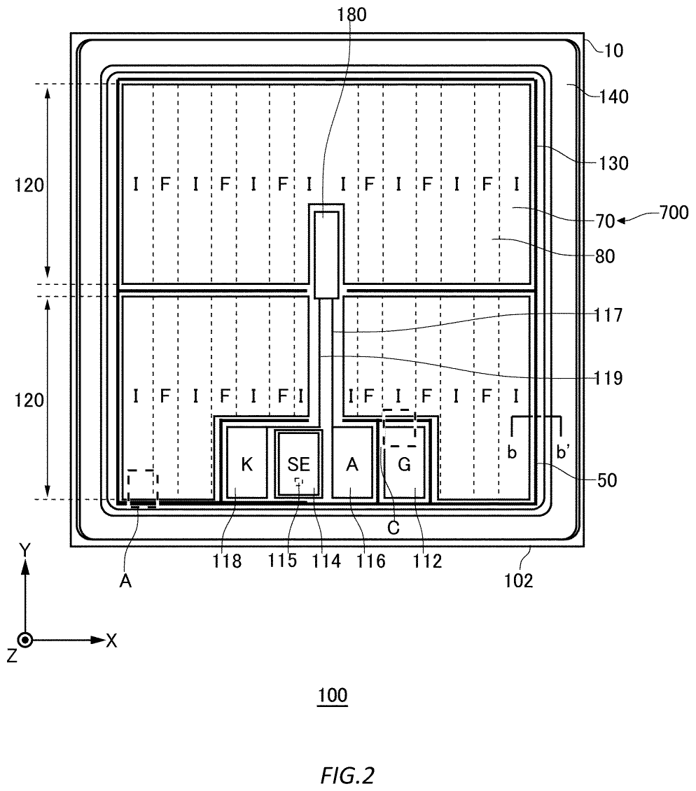

FIG. 2 shows a top view of a modified example of the semiconductor device 100. In the present example, only some members of the semiconductor device 100 are shown, and some members are omitted. The semiconductor device 100 in the present example includes a gate pad 112, a sensing electrode 114, an anode pad 116, a cathode pad 118, and a temperature sensing portion 180.

A semiconductor substrate 10 has end sides 102 in a top view. The semiconductor substrate 10 in the present example has two sets of end sides 102 facing each other in a top view. In the present example, the X axis and the Y axis are parallel to any of the end sides 102.

The semiconductor substrate 10 is provided with active regions 120. An active region 120 is a region where a main current flows in the depth direction between a front surface 21 and a back surface 23 of the semiconductor substrate 10 if the semiconductor device 100 is operated. Although an emitter electrode 52 is provided above the active region 120, it is omitted in the present figure.

The active region 120 is provided with at least one of transistor portions 70 each including a transistor element such as an IGBT, or diode portions 80 each including a diode element such as a freewheeling diode (FWD). In the example of FIG. 2, the transistor portions 70 and the diode portions 80 are alternately arranged along a predefined array direction (the X axis direction in the present example) at the front surface 21 of the semiconductor substrate 10. In another example, the active region 120 may be provided with only one of the transistor portions 70 and the diode portions 80.

In the present example, a region where a transistor portion 70 is arranged is denoted by a symbol “I”, and a region where a diode portion 80 is arranged is denoted by a symbol “F”. The transistor portion 70 and the diode portion 80 each may have a longitudinal length in an extending direction. In other words, a length of the transistor portion 70 in the Y axis direction is larger than its width in the X axis direction. Similarly, a length of the diode portion 80 in the Y axis direction is larger than its width in the X axis direction. The extending direction of the transistor portion 70 and the diode portion 80 may be the same as a longitudinal direction of each trench portion.

The diode portion 80 is a region obtained by projecting a cathode region 82 provided on a back surface 23 side of the semiconductor substrate 10 onto an upper surface of the semiconductor substrate 10. The cathode region 82 will be described later. At the back surface 23 of the semiconductor substrate 10, a region other than the cathode region 82 may be provided with a first implantation region 221 or a second implantation region 222.

The semiconductor device 100 may have one or more pads above the semiconductor substrate 10. The semiconductor device 100 in the present example has the gate pad 112, the sensing electrode 114, the anode pad 116, and the cathode pad 118. Each pad is arranged in a region near an end side 102. The region near the end side 102 refers to a region between the end side 102 and the emitter electrode 52 in a top view. When the semiconductor device 100 is mounted, each pad may be connected to an external circuit via a wiring line such as a wire.

A gate potential is applied to the gate pad 112. The gate pad 112 is electrically connected to a gate conductive portion 44 of a gate trench portion 40 of the active region 120. The semiconductor device 100 includes a gate wiring line 130 connecting the gate pad 112 and the gate trench portion 40. It should be noted that, in FIG. 2, the gate wiring line 130 is omitted.

The sensing electrode 114 is electrically connected to a current sensing unit 115 provided below the sensing electrode 114. The sensing electrode 114 detects a current flowing through the current sensing unit 115. The current sensing unit 115 detects a current flowing through the transistor portions 70. The current sensing unit 115 has a structure corresponding to the transistor portion 70, simulates operation of the transistor portion 70, and allows a current proportional to the current flowing through the transistor portion 70 to flow therethrough. The current flowing through the transistor portion 70 can be monitored by using the current sensing unit 115.

The temperature sensing portion 180 is provided on top of or inside the semiconductor substrate 10. In the present example, it is provided on a well region 17 between transistor portions 70 in a central portion of the semiconductor device 100. The temperature sensing portion 180 senses temperature of the active regions 120. A specific configuration of the temperature sensing portion 180 will be omitted.

The anode pad 116 is electrically connected to an anode region of the temperature sensing portion 180. The anode pad 116 is electrically connected to the anode region of the temperature sensing portion 180 by an anode wiring line 117.

The cathode pad 118 is electrically connected to a cathode region of the temperature sensing portion 180. The cathode pad 118 is electrically connected to the cathode region of the temperature sensing portion 180 by a cathode wiring line 119.

The gate wiring line 130 includes a gate metal layer 50 formed of metal such as aluminum, and a gate runner 48 formed of a semiconductor made of polysilicon to which impurities have been added or the like. The gate runner 48 will be described later. The gate wiring line may be composed of either one of the gate metal layer 50 or a connecting portion 25, or of an appropriate combination of them both.

An edge termination structure portion 140 is provided at the front surface 21 of the semiconductor substrate 10. The edge termination structure portion 140 is provided between the active regions 120 and the end sides 102 in a top view. The edge termination structure portion 140 reduces electric field strength on a front surface 21 side of the semiconductor substrate 10. The edge termination structure portion 140 may include at least one of a guard ring, a field plate, or a RESURF which is annularly provided enclosing the active regions 120.

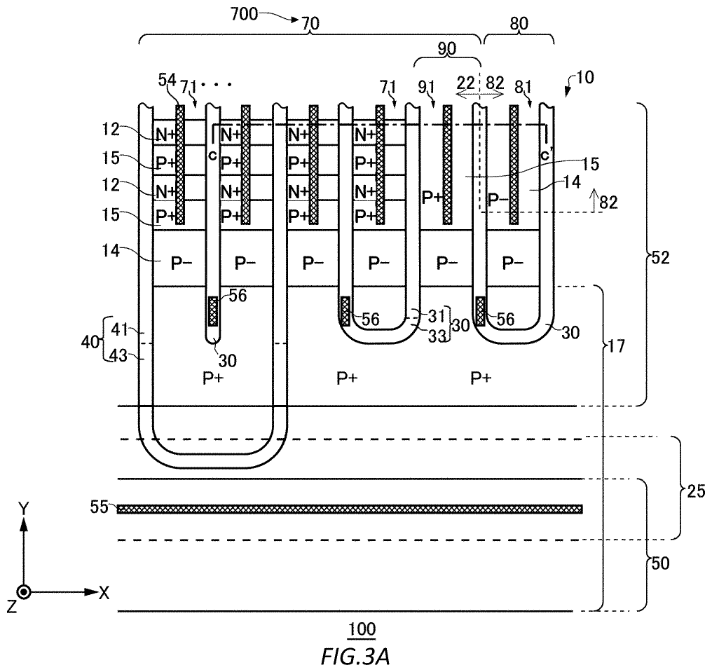

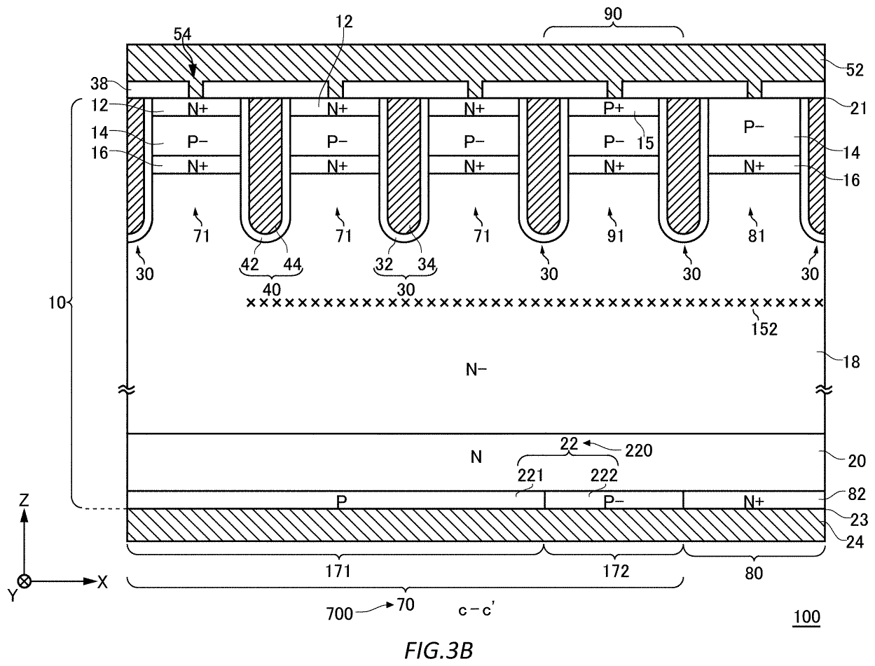

FIG. 3A shows a top view of a modified example of the semiconductor device 100. The semiconductor device 100 in the present example includes a transistor portion 70 and a diode portion 80. The present figure is an enlarged view of an upper surface of a region A in FIG. 2.

The semiconductor device 100 in the present example includes a gate trench portion 40, dummy trench portions 30, emitter regions 12, base regions 14, contact regions 15, and the well region 17 which are provided inside the semiconductor substrate 10 on the front surface 21 side. Each of the gate trench portion 40 and the dummy trench portions 30 is one example of the trench portion.

Like the gate trench portion 40, the dummy trench portions 30 in the present example may have a U shape at the front surface 21 of the semiconductor substrate 10. That is, a dummy trench portion 30 may have: two extending parts 31 which extend along the extending direction; and a connecting part 33 which connects the two extending parts 31.

The semiconductor device 100 in the present example includes the emitter electrode 52 and the gate metal layer 50 which are provided above the front surface 21 of the semiconductor substrate 10. The emitter electrode 52 and the gate metal layer 50 are provided separate from each other. The transistor portion 70 in the present example includes a boundary portion 90 located at a boundary between the transistor portion 70 and the diode portion 80. It is to be noted that the semiconductor device 100 may not include the boundary portion 90.

The boundary portion 90 is a region provided in the transistor portion 70 and being adjacent to the diode portion 80. The boundary portion 90 has a contact region 15 at the front surface 21 of the semiconductor substrate 10. The boundary portion 90 in the present example does not have an emitter region 12. In one example, trench portions in the boundary portion 90 are dummy trench portions 30. The boundary portion 90 in the present example is arranged such that the dummy trench portions 30 are located at its both ends in the X axis direction.

A contact hole 54 is provided above a base region 14 in the diode portion 80. A contact hole 54 is provided above the contact region 15 in the boundary portion 90. None of the contact holes 54 is provided above well regions 17 provided at its both ends in the Y axis direction.

A mesa portion 91 is provided in the boundary portion 90. The mesa portion 91 has a contact region 15 at the front surface 21 of the semiconductor substrate 10. The mesa portion 91 in the present example has a base region 14 and the well region 17 on a negative side in the Y axis direction.

A mesa portion 81 is provided in a region sandwiched between dummy trench portions 30 adjacent to each other in the diode portion 80. The mesa portion 81 includes a base region 14 at the front surface 21 of the semiconductor substrate 10. The mesa portion 81 in the present example has the well region 17 on the negative side in the Y axis direction.

The emitter regions 12 are provided in mesa portions 71, but emitter regions 12 may not be provided in the mesa portion 81 and the mesa portion 91. The contact regions 15 are provided in the mesa portions 71 and the mesa portion 91, but a contact region 15 may not be provided in the mesa portion 81.

FIG. 3B shows one example of a cross section taken along a line c-c′ in FIG. 3A. The semiconductor device 100 in the present example includes a front surface side lifetime control region 152. It is to be noted that the semiconductor device 100 may not include a front surface side lifetime control region 152. The semiconductor device 100 in the present example includes, on the back surface 23 side in a buffer region 20, the first implantation region 221, the second implantation region 222, and the cathode region 82.

The contact region 15 is provided above the base region 14 in the mesa portion 91. The contact region 15 is provided in contact with dummy trench portions 30 in the mesa portion 91. In another cross section, a contact region 15 may be provided at the front surface 21 in the mesa portion 71.

Accumulation regions 16 are provided in a transistor portion 70 and a diode portion 80. The accumulation regions 16 in the present example are provided over entire surfaces of the transistor portion 70 and the diode portion 80. It is to be noted that an accumulation region 16 may not be provided in the diode portion 80.

The cathode region 82 is provided below the buffer region 20 in the diode portion 80. A boundary between a collector region 22 and the cathode region 82 is a boundary between the transistor portion 70 and the diode portion 80. That is, the collector region 22 is provided below the boundary portion 90 in the present example.

In FIG. 3B, the second implantation region 222 is provided below the boundary portion 90. That is, a second implantation portion 172 is provided below the boundary portion 90 in the present example. It is to be noted that the first implantation region 221 may be provided below the boundary portion 90. That is, a first implantation portion 171 may be provided below the boundary portion 90.

As described above, the semiconductor device 100 including a vertical element 700 having the transistor portion 70 may further include the diode portion 80. The vertical element 700 may have the boundary portion 90 at a boundary with the diode portion 80. The boundary between the vertical element 700 and the diode portion 80 may be a boundary between an implantation region 220 and the cathode region 82. Below the boundary portion 90, the second implantation portion 172 may be provided or the first implantation portion 171 may be provided.

The front surface side lifetime control region 152 is provided on the front surface 21 side relative to a center of the semiconductor substrate 10 in the depth direction of the semiconductor substrate 10. The front surface side lifetime control region 152 in the present example is provided in a drift region 18. The front surface side lifetime control region 152 is provided in both the transistor portion 70 and the diode portion 80. The front surface side lifetime control region 152 may be provided in the diode portion 80 and the boundary portion 90, and may not be provided in part of the transistor portion 70. Below the front surface side lifetime control region 152, the back surface 23 of the semiconductor substrate 10 may have the first implantation region 221 and the second implantation region 222. The front surface side lifetime control region 152 can suppress hole implantation from the diode portion 80 and the transistor portion 70, and reduce a reverse recovery loss.

The front surface side lifetime control region 152 is provided extending from the diode portion 80 to the transistor portion 70. The front surface side lifetime control region 152 may be formed through irradiation from the front surface 21 of the semiconductor substrate 10. The front surface side lifetime control region 152 may be formed through irradiation from the back surface 23 side of the semiconductor substrate 10. The front surface side lifetime control region 152 in the present example is provided below the gate trench portion 40. When a particle beam or the like for forming the front surface side lifetime control region 152 passes through a MOS gate structure of the semiconductor device 100, defects may be generated at a boundary surface between a gate oxide film and the semiconductor substrate.

The semiconductor device 100 may be a power semiconductor device such as for controlling electrical power. The semiconductor device 100 in the present example may have a vertical semiconductor structure in which a back surface side metal layer is provided on the back surface 23 side of the semiconductor substrate 10. It is to be noted that the semiconductor device 100 may have a horizontal semiconductor structure in which a metal layer is not provided on the back surface 23 side.

It should be noted that, in the present example, an RC-IGBT having a trench gate structure is described as an example of the semiconductor device 100. It is to be noted that the semiconductor device 100 may be an IGBT having a planar gate structure, or may be an IGBT of a reverse blocking type. The semiconductor device 100 may include an N channel MOSFET, or may include a P channel MOSFET. As another example, the semiconductor device 100 may be a bipolar PIN diode, or may be a schottky barrier diode. It is to be noted that the semiconductor device 100 is not limited thereto.

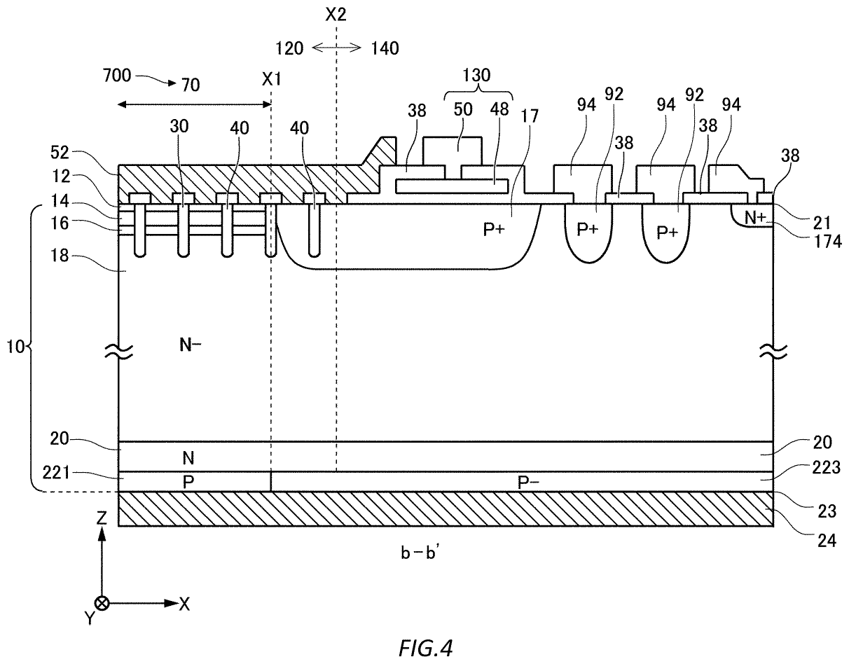

FIG. 4 shows one example of a cross section taken along a line b-b′ in FIG. 2. FIG. 4 shows a state of a vicinity of a boundary X2 between the active region 120 and the edge termination structure portion 140 of the semiconductor device 100 in the present example. The edge termination structure portion 140 has the well region 17, a plurality of guard rings 92, a plurality of field plates 94, the gate wiring line 130, and a channel stopper 174.

The well region 17 is a region of the P+ type having a higher doping concentration than a base region 14. The well region 17 is provided extending from the front surface 21 of the semiconductor substrate 10 to a position deeper than a lower end of a trench portion. The active region 120 is more easily separated from the edge termination structure portion 140 by providing the well region 17. A region enclosed by the well region 17 in a top view may be defined as the active region 120. One or more trench portions may be provided inside the well region 17. Providing, in the well region 17, a trench portion, among a plurality of trench portions, which is arranged at an end can reduce electric field strength on the trench portion.

The gate wiring line 130 is provided above the well region 17. The gate wiring line 130 in the present example includes the gate metal layer 50 formed of metal such as aluminum, and the gate runner 48 formed of a semiconductor made of polysilicon to which impurities have been added or the like. The gate runner 48 is arranged above the well region 17 with an interlayer dielectric film 38 sandwiched therebetween. The gate metal layer 50 is arranged above the gate runner 48 with the interlayer dielectric film 38 sandwiched therebetween. The gate metal layer 50 and the gate runner 48 are connected through a through hole provided in the interlayer dielectric film 38. Below the gate runner 48, a back surface low implantation region 223 may be provided at the back surface 23 of the semiconductor substrate 10.

The back surface low implantation region 223 is a region of a second conductivity type provided extending from a position below the edge termination structure portion 140 to a position below the active region 120. In one example, the back surface low implantation region 223 is of the P− type. The back surface low implantation region 223 may be provided so as to have a boundary X1 being in contact with the first implantation region 221 at the back surface 23 of the semiconductor substrate 10. In addition, the back surface low implantation region 223 may be provided so as to have a boundary being in contact with the second implantation region 222 at the back surface 23 of the semiconductor substrate 10.

A doping concentration in the back surface low implantation region 223 may be lower than a doping concentration in the first implantation region 221. In one example, the doping concentration in the back surface low implantation region 223 may be 1E15 cm⁻³ or higher, and may be equal to or lower than 0.5 times the doping concentration in the first implantation region 221.

The doping concentration in the back surface low implantation region 223 may be the same as a doping concentration in the second implantation region 222, or may be lower than a doping concentration in the second implantation region 222. In one example, the doping concentration in the back surface low implantation region 223 may be equal to or higher than 0.01 times the doping concentration in the first implantation region 221, and may be equal to or lower than 0.5 times the doping concentration in the first implantation region 221.

The boundary X1 between the first implantation region 221 and the back surface low implantation region 223 may be on an active region 120 side relative to the boundary X2 between the active region 120 and the edge termination structure portion 140. Forming the back surface low implantation region 223 having a lower doping concentration than the first implantation region 221 below the edge termination structure portion 140 suppresses hole implantation from the back surface 23 in the edge termination structure portion 140, and can improve a breakdown voltage of the semiconductor device 100.

Each of the guard rings 92 may be provided so as to enclose the active region 120 at the front surface 21. The plurality of guard rings 92 may have a function of expanding a depletion layer generated in the active region 120 toward an outside of the semiconductor substrate 10. This can prevent the electric field strength inside the semiconductor substrate 10, and can improve the breakdown voltage of the semiconductor device 100.

The guard rings 92 in the present example are semiconductor regions of the P+ type formed through ion irradiation near the front surface 21. A depth of a bottom portion of a guard ring 92 may be greater than depths of bottom portions of a gate trench portion 40 and a dummy trench portion 30.

Upper surfaces of the guard rings 92 are covered with the interlayer dielectric film 38. The field plates 94 are formed of a conductive material such as metal or polysilicon. The field plates 94 may be formed of the same material as that of the gate metal layer 50 or the emitter electrode 52. The field plates 94 are provided on the interlayer dielectric film 38. A field plate 94 is connected to the guard ring 92 through a through hole provided in the interlayer dielectric film 38.

The channel stopper 174 is provided being exposed on the front surface 21 and a side surface at the end side 102. The channel stopper 174 is a region of the N type having a higher doping concentration than a drift region 18. The channel stopper 174 has a function of terminating the depletion layer generated in the active region 120 at the end side 102 of the semiconductor substrate 10.

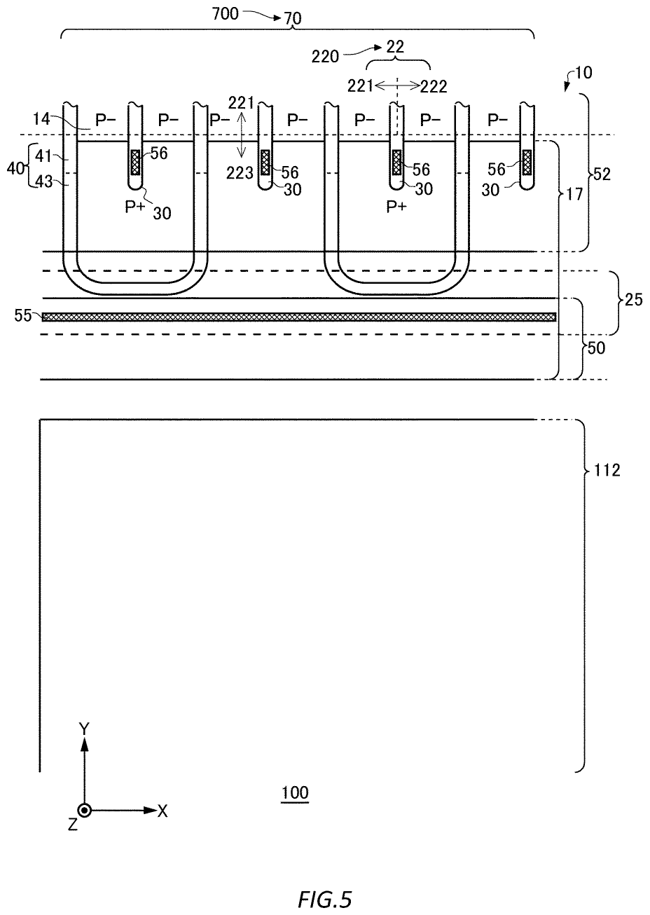

FIG. 5 shows a top view of a modified example of the semiconductor device 100. The present figure is an enlarged view of an upper surface of a region C in FIG. 2.

FIG. 5 is an enlarged view of a vicinity of a boundary between the gate pad 112 and a transistor portion 70 in the modified example of the semiconductor device 100. As indicated by dotted lines and arrows in FIG. 5, a boundary between a collector region 22 and a back surface low implantation region 223 is on a transistor portion 70 side relative to a boundary between the transistor portion 70 and the gate pad 112. That is, the back surface low implantation region 223 may be provided below the gate pad 112. Providing, below the gate pad 112, the back surface low implantation region 223 having a lower doping concentration than the first implantation region 221 suppresses hole implantation from the back surface 23 in the gate pad 112, and can improve a breakdown voltage of the semiconductor device 100.

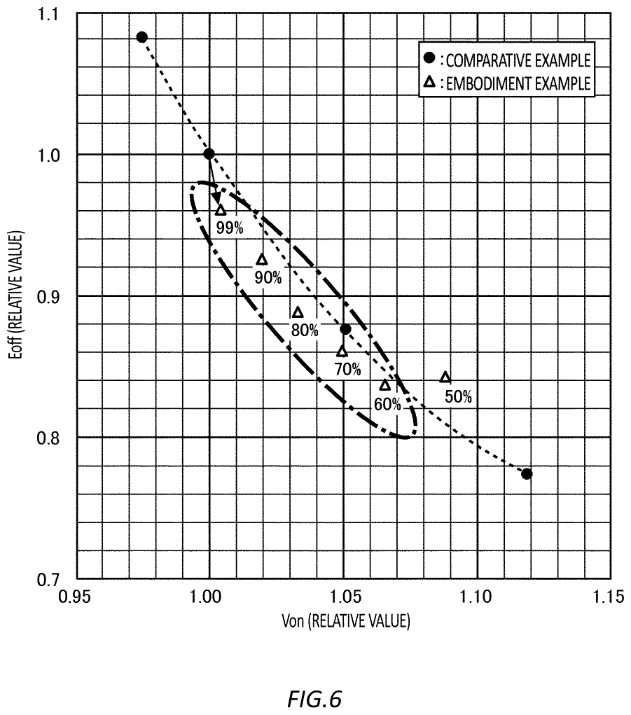

FIG. 6 is a figure showing a relationship between an area percentage of a first implantation portion 171 and Von-Eoff in a transistor portion 70 of the semiconductor device 100 in the present example. When a percentage of the first implantation portion 171 decreases, carrier implantation efficiency of the semiconductor device 100 decreases, so Von increases and Eoff decreases. At the back surface 23 in the transistor portion 70, the percentage of the first implantation portion may be 60% or higher, and may be 99% or lower. A minimum dimension of one region of a second implantation portion 172 may be 0.1 μm or greater and 40 μm or smaller, or may be 1 μm or greater and 20 μm or smaller. Von-Eoff trade-off characteristics are improved by decreasing Eoff while suppressing increase in Von by providing the second implantation portion 172 to optimize an effect of conductivity modulation compared to a conventional example.

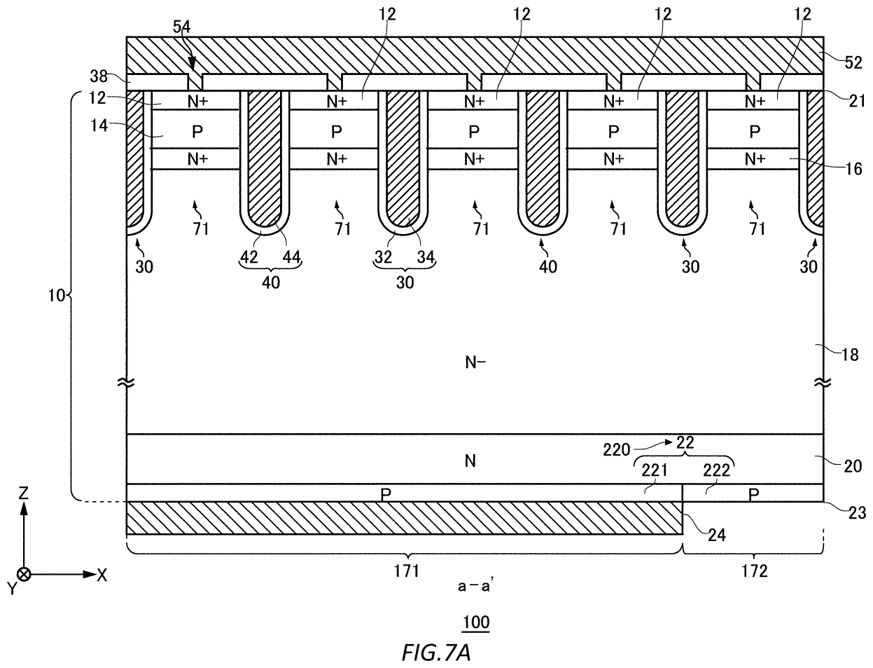

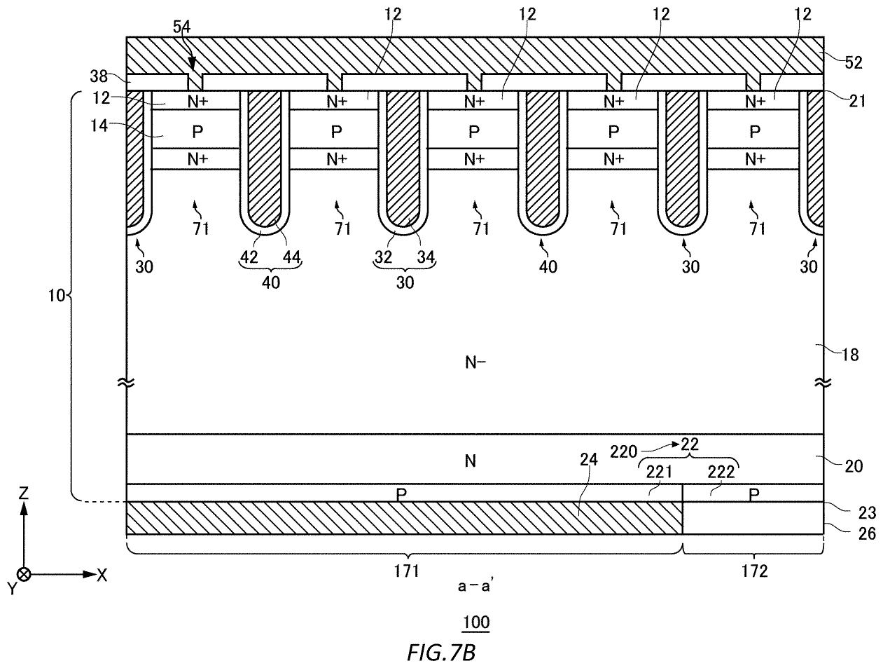

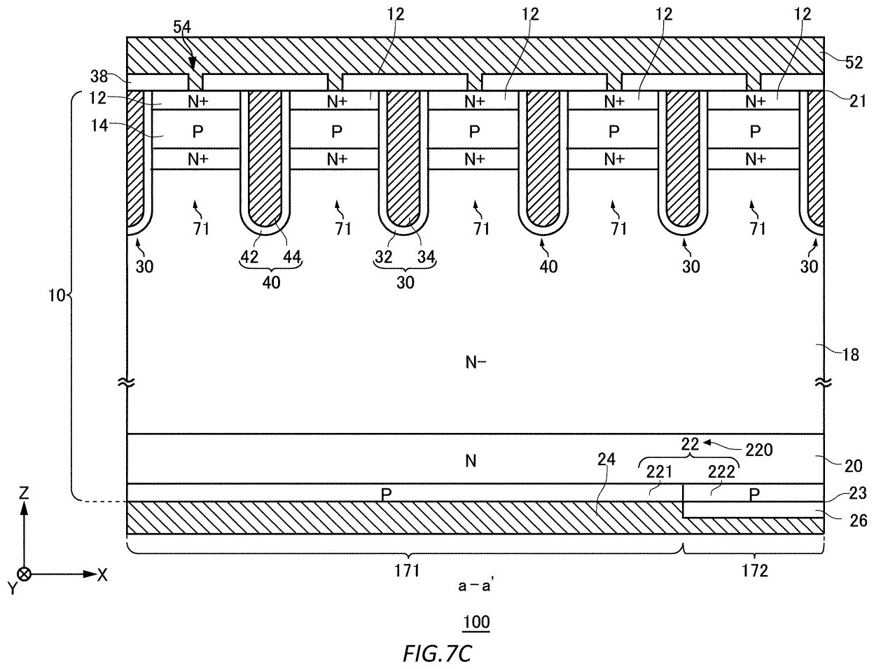

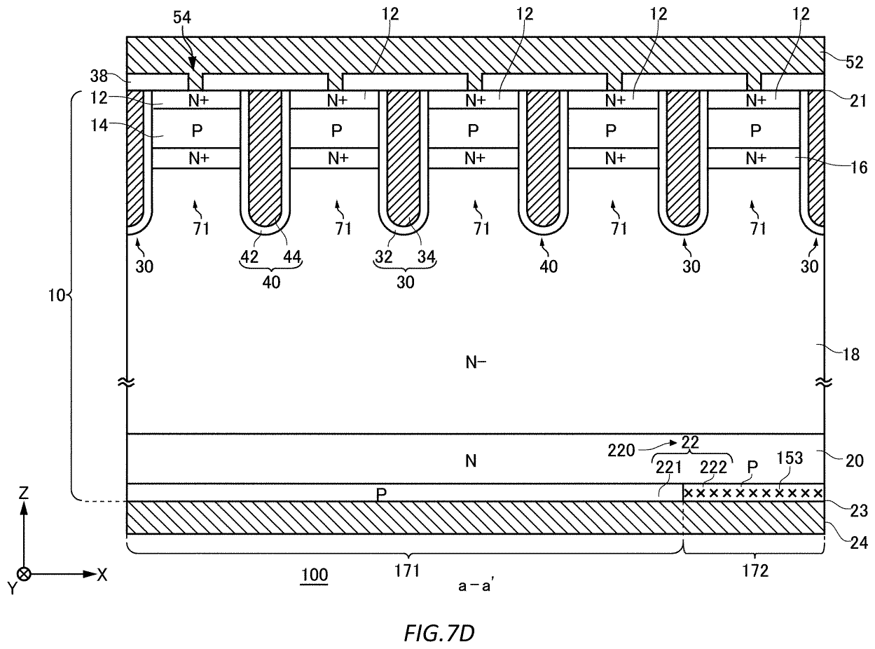

FIG. 7A is a figure showing one example of a cross section of a modified example of the semiconductor device 100. The present figure shows one example of the cross section taken along the line a-a′ of the modified example of the semiconductor device 100 shown in FIG. 1A. Differences with the cross sectional view shown in FIG. 1B will be described below.

In the modified example shown in FIG. 7A, a second implantation region 222 is not of the P− type, but is of the P type. That is, in the present example, a first implantation region 221 and the second implantation region 222 may have the same doping concentration.

In the present example, a back surface electrode 24 is in contact with a semiconductor substrate 10 at a back surface 23 of the semiconductor substrate 10 in a first implantation portion 171. On the other hand, the back surface electrode 24 is not in contact with the semiconductor substrate 10 at the back surface 23 of the semiconductor substrate 10 in a second implantation portion 172. That is, a back surface electrode 24 is not provided in the second implantation portion 172.

Since a back surface electrode 24 is not provided in the second implantation portion 172, carrier implantation efficiency in the second implantation portion 172 is lower than carrier implantation efficiency in the first implantation portion 171. As a result, in a drift region 18 of the second implantation portion 172, a total quantity of carriers decreases during conductivity modulation, and a switching loss Eoff can be reduced.

FIG. 7B is a figure showing one example of a cross section of a semiconductor device 100 in a modified example different from the modified example shown in FIG. 7A. Differences with the cross sectional view shown in FIG. 7A will be described below.

In the modified example shown in FIG. 7B, a dielectric film 26 is in contact with a semiconductor substrate 10 at a back surface 23 of the semiconductor substrate 10 in a second implantation portion 172. This makes carrier implantation efficiency in the second implantation portion 172 lower than carrier implantation efficiency in a first implantation portion 171.

In addition, the dielectric film 26 may be replaced with another configuration as long as the configuration is capable of electrical insulation. In one example, the dielectric film 26 may be an oxide film such as SiO₂, or may be a nitride film such as AlN. In addition, in one example, the dielectric film 26 may be a schottky junction electrode. The schottky junction electrode may be composed of metal such as Ni, Cu, or Au.

FIG. 7C is a figure showing one example of a cross section of a semiconductor device 100 in a modified example different from the modified example shown in FIG. 7B. Differences with the cross sectional view shown in FIG. 7B will be described below.

In the modified example shown in FIG. 7C, below a dielectric film 26 provided so as to be in contact with a back surface 23 of a semiconductor substrate 10 in a second implantation portion 172, a back surface electrode 24 is provided so as to be in contact with the dielectric film 26. This can make carrier implantation efficiency in the second implantation portion 172 lower than carrier implantation efficiency in a first implantation portion 171 without removing part of the back surface electrode 24 from the semiconductor device 100.

FIG. 7D is a figure showing one example of a cross section of a semiconductor device 100 in a modified example different from the modified example shown in FIG. 7C. Differences with the cross sectional view shown in FIG. 7C will be described below.

In the modified example shown in FIG. 7D, a back surface electrode 24 is provided so as to be in contact with a back surface 23 of a semiconductor substrate 10 in a second implantation portion 172. That is, as in the example shown in FIG. 1B, the back surface electrode 24 is provided over an entire surface of the back surface 23 of the semiconductor substrate 10. On the other hand, in the modified example shown in FIG. 7D, a second implantation region 222 has crystal defects 153. A lifetime in the second implantation region 222 may be shorter than a lifetime in a first implantation region 221. This can make carrier implantation efficiency in the second implantation portion 172 lower than carrier implantation efficiency in a first implantation portion 171 without removing part of the back surface electrode 24 from the semiconductor device 100.

The crystal defects 153 may be formed by performing ion implantation of an element having a low activation rate, such as Ar, Si, C, O, He, or H, into the second implantation region 222. That is, the second implantation region 222 may contain more of at least any one element of Ar, Si, C, O, He, or H than the first implantation region 221. The crystal defects 153 may be formed by irradiating the second implantation region 222 with light.

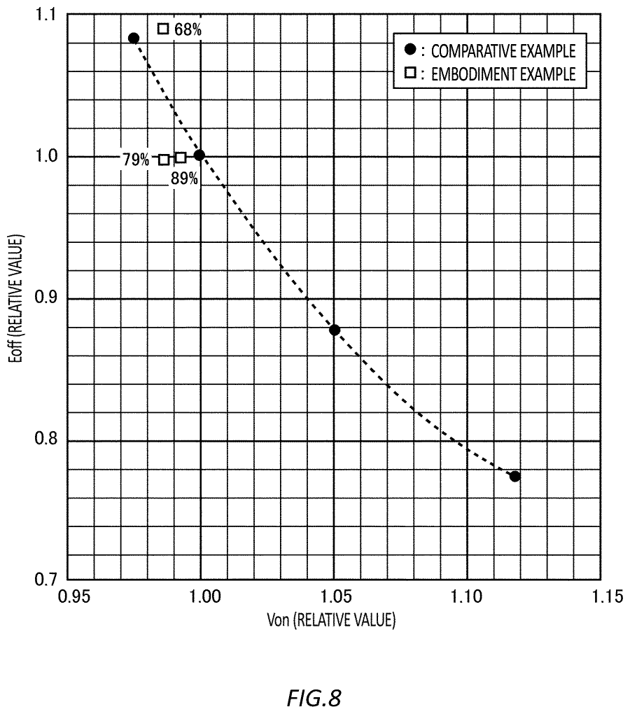

FIG. 8 is a figure showing a relationship between an area percentage of a first implantation portion 171 and Von-Eoff in a transistor portion 70 of a semiconductor device 100 as a modified example. Decrease in a percentage of the first implantation portion 171 can reduce Von almost without affecting a value of Eoff. At a back surface 23 in the transistor portion 70, the percentage of the first implantation portion may be 75% or higher, and may be 90% or lower. Providing a second implantation portion 172 improves Von-Eoff trade-off characteristics.

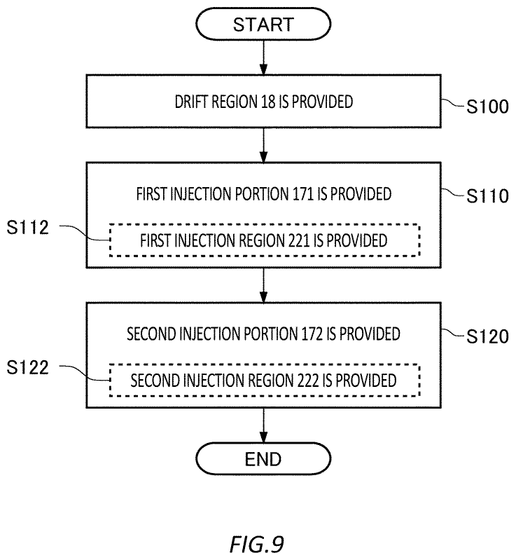

FIG. 9 is a flowchart showing one example of a process of manufacturing a semiconductor device 100. In a step S100, a drift region 18 of a first conductivity type is formed in a semiconductor substrate 10. The step S100 in which the drift region 18 is formed may not be an independent process. That is, the drift region 18 may be a region of the semiconductor substrate 10 which is left without another doping region being formed therein, and a step in which another region is formed may be the step S100 in which the drift region 18 is formed.

In a step S110, a first implantation portion 171 is provided below the drift region 18. The step S110 in which the first implantation portion 171 is provided may have a step S112 in which a first implantation region 221 of a second conductivity type is provided below the drift region 18 in the semiconductor substrate 10. The step S112 in which the first implantation region 221 is provided may include a step in which light irradiation is performed.

In a step S120, a second implantation portion 172 having lower carrier implantation efficiency than the first implantation portion 171 is provided below the drift region 18. The step in which the second implantation portion 172 is provided may have a step S122 in which a second implantation region 222 of the second conductivity type is provided below the drift region 18 in the semiconductor substrate 10. The step S122 in which the second implantation region 222 is provided may include a step in which light is applied with higher energy than light applied in the step S112 in which the first implantation region 221 is provided. Crystal defects 153 can be formed in the second implantation region 222 by applying the light with higher energy than light applied in the step S112 in which the first implantation region 221 is provided. This can make carrier implantation efficiency in the second implantation portion 172 lower than carrier implantation efficiency in the first implantation portion 171.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” for convenience in the claims, embodiments, or diagrams, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: back surface electrode; 25: connecting portion; 26: dielectric film; 30: dummy trench portion; 31: extending part; 32: dummy dielectric film; 33: connecting part; 34: dummy conductive portion; 38: interlayer dielectric film; 40: gate trench portion; 41: extending part; 42: gate dielectric film; 43: connecting part; 44: gate conductive portion; 48: gate runner; 50: gate metal layer; 52: emitter electrode; 54: contact hole; 55: contact hole; 56: contact hole; 70: transistor portion; 71: mesa portion; 80: diode portion; 81: mesa portion; 82: cathode region; 90: boundary portion; 91: mesa portion; 92: guard ring; 94: field plate; 100: semiconductor device; 102: end side; 112: gate pad; 114: sensing electrode; 115: current sensing unit; 116: anode pad; 117: anode wiring line; 118: cathode pad; 119: cathode wiring line; 120: active region; 130: gate wiring line; 140: edge termination structure portion; 152: front surface side lifetime control region; 153: crystal defect; 171: first implantation portion; 172: second implantation portion; 174: channel stopper; 180: temperature sensing portion; 220: implantation region; 221: first implantation region; 222: second implantation region; 223: back surface low implantation region; and 700: vertical element.

What is claimed is:

1. A semiconductor device comprising a vertical element, wherein
the vertical element has:
a drift region of a first conductivity type provided in a semiconductor substrate;
a first implantation portion provided below the drift region; and
a second implantation portion provided below the drift region and having lower carrier implantation efficiency than the first implantation portion,
at a back surface of the semiconductor substrate, an area of the first implantation portion is larger than an area of the second implantation portion, and
the vertical element has the first implantation portion and the second implantation portion which are alternately provided in a predetermined direction.

2. The semiconductor device according to claim 1, wherein the vertical element has the first implantation portion and the second implantation portion which are regularly provided.

3. The semiconductor device according to claim 1, comprising a plurality of trench portions provided at a front surface of the semiconductor substrate, wherein
the predetermined direction has a slope of 0 degrees or more and 90 degrees or less with respect to an extending direction of the plurality of trench portions.

4. The semiconductor device according to claim 1, wherein
the first implantation portion includes a first implantation region of a second conductivity type provided below the drift region in the semiconductor substrate, and
a doping concentration in the first implantation region is 1E16 cm⁻³ or higher and 1E18 cm⁻³ or lower.

5. The semiconductor device according to claim 4, wherein
the second implantation portion includes a second implantation region of the second conductivity type provided below the drift region in the semiconductor substrate, and
a doping concentration in the second implantation region is lower than the doping concentration in the first implantation region.

6. The semiconductor device according to claim 5, wherein the doping concentration in the second implantation region is 1E15 cm⁻³ or higher, and is equal to or lower than 0.5 times the doping concentration in the first implantation region.

7. The semiconductor device according to claim 5, comprising:
an active region provided in the semiconductor substrate;
an edge termination structure portion enclosing the active region in the semiconductor substrate; and
a back surface low implantation region having a lower doping concentration than the first implantation region, which extends from a position below the edge termination structure portion to a position below the active region and is in direct contact with the first implantation region, wherein
a boundary between the first implantation region and the back surface low implantation region is on a side of the active region relative to a boundary between the active region and the edge termination structure portion.

8. The semiconductor device according to claim 7, wherein a doping concentration in the back surface low implantation region is 1E15 cm⁻³ or higher, and is equal to or lower than 0.5 times the doping concentration in the first implantation region.

9. The semiconductor device according to claim 7, wherein a doping concentration in the back surface low implantation region is equal to or higher than 0.01 times and equal to or lower than 0.5 times the doping concentration in the first implantation region.

10. The semiconductor device according to claim 7, comprising a gate pad portion which is, outside the active region, provided above the semiconductor substrate and electrically connected to a gate conductive portion of the vertical element, wherein
a region below the gate pad portion is the back surface low implantation region.

11. The semiconductor device according to claim 10, further comprising a gate runner electrically connecting the gate pad portion and the gate conductive portion, wherein
a region below the gate runner is the back surface low implantation region.

12. The semiconductor device according to claim 5, wherein a percentage of the first implantation portion at the back surface in the vertical element is 60% or higher and 99% or lower.

13. The semiconductor device according to claim 1, wherein
the first implantation portion has a first implantation region of a second conductivity type provided below the drift region in the semiconductor substrate,
the second implantation portion has a second implantation region of the second conductivity type provided below the drift region in the semiconductor substrate, and
in the first implantation portion, the back surface of the semiconductor substrate is in contact with a back surface electrode, and in the second implantation portion, the back surface of the semiconductor substrate is not in contact with the back surface electrode.

14. The semiconductor device according to claim 13, wherein the second implantation portion has a dielectric film provided below the second implantation region, and the dielectric film is in contact with the back surface of the semiconductor substrate.

15. The semiconductor device according to claim 1, wherein
the second implantation portion has:
a second implantation region of a second conductivity type provided below the drift region in the semiconductor substrate;
a dielectric film being in contact with the second implantation region at the back surface of the semiconductor substrate; and
a back surface electrode being in contact with the dielectric film below the dielectric film.

16. The semiconductor device according to claim 13, wherein a percentage of the first implantation portion in the vertical element is 75% or higher and 90% or lower.

17. The semiconductor device according to claim 1, wherein
the first implantation portion has a first implantation region of a second conductivity type provided below the drift region in the semiconductor substrate,
the second implantation portion has a second implantation region of the second conductivity type provided below the drift region in the semiconductor substrate, and
a lifetime in the second implantation region is shorter than a lifetime in the first implantation region.

18. The semiconductor device according to claim 1, wherein
the first implantation portion has a first implantation region of a second conductivity type provided below the drift region in the semiconductor substrate,
the second implantation portion has a second implantation region of the second conductivity type provided below the drift region in the semiconductor substrate, and
the second implantation region contains more of at least any one element of Ar, Si, C, O, He, or H than the first implantation region.

19. The semiconductor device according to claim 1, wherein
the vertical element has a transistor portion, and
the semiconductor device is an RC-IGBT further including a diode portion.

20. The semiconductor device according to claim 19, wherein at a boundary between the transistor portion and the diode portion, the back surface of the transistor portion is the first implantation portion.

21. The semiconductor device according to claim 19, wherein at a boundary between the transistor portion and the diode portion, the back surface of the transistor portion is the second implantation portion.

22. The semiconductor device according to claim 19, comprising a lifetime control region including a lifetime killer, which extends from the diode portion to the transistor portion and is provided in the drift region.

23. A method for manufacturing a semiconductor device including a vertical element, the method comprising:
forming a drift region of a first conductivity type in a semiconductor substrate;
providing a first implantation portion below the drift region in the semiconductor substrate; and
providing a second implantation portion having lower carrier implantation efficiency than the first implantation portion below the drift region in the semiconductor substrate, wherein
at a back surface of the semiconductor substrate, an area of the first implantation portion is larger than an area of the second implantation portion, and
the first implantation portion and the second implantation portion are alternately provided in a predetermined direction.

24. The method for manufacturing a semiconductor device according to claim 23, wherein
the providing the first implantation portion has providing a first implantation region of a second conductivity type below the drift region in the semiconductor substrate,
the providing the second implantation portion has providing a second implantation region of the second conductivity type below the drift region in the semiconductor substrate,
the providing the first implantation region includes performing light irradiation, and
the providing the second implantation region includes applying light with higher energy than light applied in the providing the first implantation region.
